(19) United States
(12) Patent Application Publication
(10) Pub. No.: US 2011/0297956 A1
(43) Pub. Date: Dec. 8, 2011

(54) METHOD FOR MANUFACTURING GALLIUM NITRIDE COMPOUND SEMICONDUCTOR, AND SEMICONDUCTOR LIGHT EMITTING ELEMENT

(75) Inventors: Ryou Kato, Osaka (JP); Masaki Fujikane, Osaka (JP); Akira Inoue, Osaka (JP); Toshiya Yokogawa, Nara (JP)

(73) Assignee: PANASONIC CORPORATION, Osaka (JP)

(21) Appl. No.: 13/201,938

(22) PCT Filed: Oct. 21, 2009
(86) PCT No.: PCT/JP2009/005526

§ 371 Date: Aug. 17, 2011

(30) Foreign Application Priority Data
Mar. 3, 2009 (JP) 2009-049642

(51) Int. Cl. H01L 33/02

(52) U.S. Cl. 257/76; 438/46; 257/E33.023

(57) ABSTRACT

The present invention is a method of manufacturing a gallium nitride-based compound semiconductor, including growing an m-plane InGaN layer whose emission peak wavelength is not less than 500 nm by metalorganic chemical vapor deposition. Firstly, step (A) of heating a substrate in a reactor is performed. Then, step (B) of supplying into the reactor a gas which contains an In source gas, a Ga source gas, and a N source gas and growing an m-plane InGaN layer of an InₓGa₁₋ₓN crystal on the substrate at a growth temperature from 700° C. to 775° C. is performed. In step (B), the growth rate of the m-plane InGaN layer is set in a range from 4.5 nm/min to 10 nm/min.

### TECHNICAL FIELD

The present invention relates to a method of manufacturing a gallium nitride-based compound semiconductor and to a semiconductor light-emitting device fabricated according to the manufacturing method.

### BACKGROUND ART

A nitride semiconductor including nitrogen (N) as a Group V element is a prime candidate for a material to make a short-wave light-emitting device because its bandgap is sufficiently wide. Among other things, gallium nitride-based compound semiconductors (which will be referred to herein as “GaN-based semiconductors”) have been researched and developed particularly extensively. As a result, blue light-emitting diodes (LEDs), green LEDs, and semiconductor laser diodes made of GaN-based semiconductors have already been used in actual products.

A gallium nitride-based semiconductor has a wurtzite crystal structure. FIG. 1 schematically illustrates a unit cell of GaN. In an AlₐGa_{b}In_{c}N (where 0≦a, b, c≦1 and a+b+c=1) semiconductor crystal, some of the Ga atoms shown in FIG. 1 may be replaced with Al and/or In atoms.

FIG. 2 shows four primitive vectors a₁, a₂, a₃ and c, which are generally used to represent planes of a wurtzite crystal structure with four indices (i.e., hexagonal indices). The primitive vector c runs in the [0001] direction, which is called a “c-axis”. A plane that intersects with the c-axis at right angles is called either a “c-plane” or a “(0001) plane”. It should be noted that the “c-axis” and the “c-plane” are sometimes referred to as “C-axis” and “C-plane”, respectively.

The wurtzite crystal structure has other typical crystallographic plane orientations than the c-plane, as shown in FIG. 3. FIG. 3(a) shows a (0001) plane. FIG. 3(b) shows a (10-10) plane. FIG. 3(c) shows a (11-20) plane. FIG. 3(d) shows a (10-12) plane. As used herein, “−” attached on the left-hand side of a Miller-Bravais index in the parentheses means a “bar” (a negative direction index). The (0001) plane, the (10-10) plane, the (11-20) plane, and the (10-12) plane are the c-plane, the m-plane, the a-plane, and the r-plane, respectively. The m-plane and the a-plane are “non-polar planes” that are parallel to the c-axis, and the r-plane is a “semi-polar plane”. Note that the “m-plane” is a generic term that collectively refers to a family of planes including (10-10), (−1010), (1-100), (−1100), (01-10) and (0-110) planes.

For years, a light-emitting device in which a gallium nitride-based compound semiconductor is used is fabricated by means of “c-plane growth”. As used herein, the “X-plane growth” means epitaxial growth that is produced perpendicularly to the X plane (where X=c, m, a, or r) of a hexagonal wurtzite structure. As for the X-plane growth, the X plane will be sometimes referred to herein as a “growing plane”. Furthermore, a layer of semiconductor crystals that have been formed as a result of the X-plane growth will be sometimes referred to herein as an “X-plane semiconductor layer”.

When a light-emitting device is fabricated using a semiconductor multilayer structure formed by means of the c-plane growth, strong internal polarization occurs in a direction perpendicular to the c-plane (c-axis direction) because the c-plane is a polar plane. The reason for occurrence of the polarization is that, on the c-plane, there is a shift in the c-axis direction between the positions of a Ga atom and a N atom. If such polarization occurs in an emission section, a quantum confinement Stark effect of carriers occurs. This effect reduces the probability of radiative recombination of carriers in the emission section and accordingly reduces the emission efficiency.

In view of such circumstances, in recent years, intensive research has been carried out on growth of a gallium nitride-based compound semiconductor on a non-polar plane, such as m-plane and a-plane, and a semi-polar plane, such as r-plane. If a non-polar plane is available as the growing plane, no polarization occurs in the layer thickness direction (crystal growth direction) of the emission section. Therefore, the quantum confinement Stark effect does not occur. Thus, a light-emitting device which potentially has high efficiency can be fabricated. Even when the growing plane is a semi-polar plane, the influence of the quantum confinement Stark effect can be greatly reduced.

FIG. 4(a) schematically illustrates the crystal structure of a nitride-based semiconductor, of which the principal surface is an m-plane, as viewed on a cross section thereof that intersects with the principal surface of the substrate at right angles. Since Ga atoms and nitrogen atoms are present on the same atomic-plane that is parallel to the m-plane, no electrical polarization will be produced perpendicularly to the m-plane. It should be noted that In and Al atoms that have been added will be located at Ga sites and will replace the Ga atoms. Even if at least some of the Ga atoms are replaced with those In or Al atoms, no electrical polarization will still be produced perpendicularly to the m-plane.

The crystal structure of a nitride-based semiconductor, of which the principal surface is a c-plane, as viewed on a cross section thereof that intersects with the principal surface of the substrate at right angles is illustrated schematically in FIG. 4(b) just for a reference. In this case, Ga atoms and nitrogen atoms are not present on the same atomic-plane, and therefore, electrical polarization will be produced perpendicularly to the c-plane. A c-plane GaN-based substrate is generally used to grow GaN-based semiconductor crystals thereon. In such a substrate, a Ga (or In) atom layer and a nitrogen atom layer that extend parallel to the c-plane are slightly misaligned from each other in the c-axis direction, and therefore, electrical polarization will be produced in the c-axis direction.

### CITATION LIST

### Patent Literature

Patent Document 1: Japanese PCT National Phase Laid-Open Publication No. 2007-537600

### SUMMARY OF INVENTION

### Technical Problem

A light-emitting device which includes a light-emitting layer formed on an m-plane that is a non-polar plane is advantageously free from occurrence of the quantum confinement Stark effect. However, crystal growth of the light-emitting layer has some critical disadvantages as compared with the c-plane growth of the prior art.

One of the disadvantages is that, when m-plane growth of an InGaN layer is performed by metalorganic chemical vapor deposition (MOCVD), In atoms are not smoothly incorporated into the crystal of InGaN. Therefore, when m-plane growth of the InₓGa₁₋ₓN (0<x<1) crystal is performed, it is difficult to increase the In mole fraction x. This is described in, for example, Patent Document 1, paragraph.

Hereinafter, in this specification, a layer of the InₓGa₁₋ₓN (0<x<1) crystal is sometimes simply referred to as “InGaN layer”. However, when the In mole fraction x is discussed, the expression of “InₓGa₁₋ₓN (0<x<1) layer” is used.

In atoms replace some of the Ga atoms of the GaN crystal. The bandgap of the InₓGa₁₋ₓN crystal varies depending on the In mole fraction x. As the In mole fraction x increases, the InₓGa₁₋ₓN bandgap decreases and approaches the bandgap of the InN crystal. As the bandgap decreases, the emission wavelength becomes longer. When the In mole fraction is increased to 15% or higher, a gallium nitride-based compound semiconductor light-emitting device can produce a long-wavelength emission, for example, blue or green.

From the viewpoint of obtaining a high quality crystal, the growth temperature of GaN that does not contain In is usually set to 1000° C. or higher. However, in the case of growing InₓGa₁₋ₓN, the growth temperature needs to be sufficiently lower than 1000° C. because In readily evaporates. Another disadvantage is that, in the case of m-plane growth, the In incorporation efficiency is lower than in the case of c-plane growth as will be described below. Thus, in that situation, it is very difficult to realize an m-plane device which is capable of producing a long-wavelength emission.

FIG. 5 is a graph which shows the relationship between the emission wavelengths of InGaN layers grown by MOCVD and the growth temperature. The graph shows the emission wavelength of an InGaN layer formed by means of the c-plane growth (hereinafter, referred to as “c-plane InGaN layer”) and the emission wavelength of an InGaN layer formed by means of the m-plane growth (hereinafter, referred to as “m-plane InGaN layer”). The abscissa axis of the graph represents the growth temperature, and the ordinate axis represents the peak wavelength. In the graph, solid diamonds ♦ represent a peak wavelength of an emission obtained from the c-plane InGaN layer, and solid circles represent a peak wavelength of an emission obtained from the m-plane InGaN layer. This graph was plotted based on the results of experiments conducted by the present inventors. The supply conditions for source gasses supplied into the reactor of the MOCVD apparatus during the growth of the InGaN layers are as follows.

TABLE 1

| | TMG | TMI | NH₃ |
|---|---|---|---|
| Plane Orientation | sccm | sccm | slm |
| of Growing Plane | (μmol/min) | (μmol/min) | (mol/min) |
| c-plane growth | 1 (3.6) | 100 (39.1) | 18 (0.8) |
| m-plane growth | 1 (3.6) | 100 (39.1) | 18 (0.8) |

Here, sccm (standard cc/minute) and slm (standard liter/minute) mean a volume flow rate which is expressed by the volume per minute of a source gas supplied into the reactor (in a converted value under the conditions of 0° C. and 1 atm). The unit of the volume of sccm is cubic centimeter [cc], and the unit of the volume of slm is liter. Also, “μmol/min” means the molar supply flow rate, which is the molar amount per minute of the source gas supplied into the reactor. TMG is trimethylgallium (Ga source gas). TMI is trimethylindium (In source gas). NH₃ is a source gas of N (nitrogen).

As seen from the graph of FIG. 5, in either case of a c-plane InGaN layer and an m-plane InGaN layer, the emission wavelength becomes longer as the growth temperature decreases. This means that, as the growth temperature decreases, the In incorporation efficiency increases, and accordingly, the In mole fraction x in the InₓGa₁₋ₓN crystal also increases. The growth temperature dependence of the emission wavelength is linear, and the absolute value of the slope of the linear dependence is relatively small in the case of m-plane growth.

It is also seen from the graph of FIG. 5 that, at the same growth temperature, the emission wavelength of the m-plane InGaN layer is significantly shorter than that of the c-plane InGaN layer. That is, the In incorporation efficiency is lower in the case of m-plane growth than in c-plane growth.

As seen from the above-described experimental result, by decreasing the growth temperature, the In mole fraction x is increased so that the emission wavelength can be made longer. However, as estimated from the extrapolated lines of the data shown in FIG. 5, formation of an InₓGa₁₋ₓN layer which is capable of emitting blue light (about 450 nm) by means of the m-plane growth requires that the growth temperature be decreased to a temperature lower than 730° C. Formation of an InₓGa₁₋ₓN layer which is capable of emitting green light (not less than 500 nm) by means of the m-plane growth requires that the growth temperature be set to a temperature lower than 700° C. When the growth temperature is decreased to a temperature near 700° C. for such reasons, the resultant m-plane InGaN layer will have many crystal defects or vacancies, significantly deteriorating the crystallinity of the m-plane InGaN layer. Moreover, the decrease of the growth temperature can be a cause of deterioration of the decomposition efficiency of NH₃ in the reactor. Therefore, performing an m-plane growth process at an extremely low temperature, e.g., lower than 700° C., is not practicable in terms of, for example, the characteristics of the light-emitting device.

The present invention was conceived for the purpose of solving the above problems. One of the objects of the present invention is to provide a method of manufacturing a gallium nitride-based compound semiconductor, in which formation of an InGaN layer by means of the m-plane growth can be performed with improved incorporation efficiency of In into the crystal.

### Solution to Problem

A gallium nitride-based compound semiconductor manufacturing method of the present invention is a method of manufacturing a gallium nitride-based compound semiconductor, including growing an m-plane InGaN layer whose emission peak wavelength is not less than 500 nm by metalorganic chemical vapor deposition, the method including the steps of: (A) heating a substrate in a reactor; and (B) supplying into the reactor a gas which contains an In source gas, a Ga source gas, and a N source gas, and growing an m-plane InGaN layer of an InₓGa₁₋ₓN crystal on the substrate at a growth temperature from 700° C. to 775° C., wherein step (B) includes setting a growth rate of the m-plane InGaN layer in a range from 4.5 nm/min to 10 nm/min.

Another gallium nitride-based compound semiconductor manufacturing method of the present invention is a method of manufacturing a gallium nitride-based compound semiconductor, including growing an m-plane InGaN layer whose emission peak wavelength is in a range from 450 nm to 500 nm by metalorganic chemical vapor deposition, the method including the steps of: (A) heating a substrate in a reactor; and (B) supplying into the reactor a gas which contains an In source gas, a Ga source gas, and a N source gas, and growing the m-plane InGaN layer of an InₓGa₁₋ₓN crystal on the substrate at a growth temperature from 775° C. to 785° C., wherein step (B) includes setting a growth rate of the en-plane InGaN layer in a range from 3 nm/min to 10 nm/min.

Still another gallium nitride-based compound semiconductor manufacturing method of the present invention is a method of manufacturing a gallium nitride-based compound semiconductor, including growing an m-plane InGaN layer whose emission peak wavelength is in a range from 425 nm to 475 nm by metalorganic chemical vapor deposition, the method including the steps of: (A) heating a substrate in a reactor; and (B) supplying into the reactor a gas which contains an In source gas, a Ga source gas, and a N source gas, and growing the m-plane InGaN layer of an InₓGa₁₋ₓN crystal on the substrate at a growth temperature from 770° C. to 790° C., wherein step (B) includes setting a growth rate of the m-plane InGaN layer to a value which is not less than 8 nm/min.

Still another gallium nitride-based compound semiconductor manufacturing method of the present invention is a method of manufacturing a gallium nitride-based compound semiconductor, including growing an m-plane InGaN layer whose emission peak wavelength is in a range from 425 nm to 475 nm by metalorganic chemical vapor deposition, the method including the steps of: (A) heating a substrate in a reactor; and (B) supplying into the reactor a gas which contains an In source gas, a Ga source gas, and a N source gas, and growing the m-plane InGaN layer of an InₓGa₁₋ₓN crystal on the substrate at a growth temperature from 770° C. to 790° C., wherein step (B) includes setting a growth rate of the m-plane InGaN layer in a range from 4 nm/min to 5 nm/min.

A semiconductor light-emitting device fabrication method of the present invention includes the steps of: providing a substrate; and forming a semiconductor multilayer structure on the substrate, the semiconductor multilayer structure including a light-emitting layer, wherein the step of forming the semiconductor multilayer structure includes forming an m-plane InGaN layer according to any of the above-described gallium nitride-based compound semiconductor manufacturing methods.

In a preferred embodiment, the light-emitting layer has a multi-quantum well structure, and the m-plane InGaN layer is a well layer included in the multi-quantum well structure.

A preferred embodiment includes the step of removing the substrate.

A semiconductor light-emitting device of the present invention includes: a light-emitting layer which includes an m-plane InGaN layer that is formed according to any of the above-described gallium nitride-based compound semiconductor manufacturing methods; and an electrode for supplying electric charge to the light-emitting layer.

### Advantageous Effects of Invention

According to the present invention, formation of an InₓGa₁₋ₓN (0<x<1) layer by means of the m-plane growth can be performed with improved incorporation efficiency of In atoms into the crystal. Accordingly, the In mole fraction (x) of the m-plane InₓGa₁₋ₓN layer can be improved. Therefore, according to the present invention, a high efficiency long-wavelength emission LED can be stably fabricated in which, in the case of forming InₓGa₁₋ₓN that functions as a light-emitting layer of a light-emitting device, a long-wavelength emission, e.g., blue or green, which is difficult for the prior art m-plane InₓGa₁₋ₓN layers to produce, can be realized, and which is free from the influence of the quantum confinement Stark effect.

### BRIEF DESCRIPTION OF DRAWINGS

FIG. 1 is a perspective view schematically illustrating a unit cell of GaN.

FIG. 2 is a perspective view showing primitive translation vectors a₁, a₂, a₃ and c of a wurtzite crystal structure.

FIGS. 3(a) to 3(d) are schematic diagrams showing representative crystallographic plane orientations of a hexagonal wurtzite structure.

FIG. 4(a) is a diagram showing a crystal structure of the m-plane. FIG. 4(b) is a diagram showing a crystal structure of the c-plane.

FIG. 5 is a graph illustrating the difference in growth temperature dependence between the wavelength of an emission from an m-plane grown InGaN layer and the wavelength of an emission from a c-plane grown InGaN layer.

FIG. 6 is a graph illustrating the variation of the emission spectrum which occurs due to the difference in growth rate of the InGaN layer in the present invention.

FIG. 7 is a graph showing the relationship between the TMG supply quantity and the growth rate of the InGaN layer in one embodiment of the present invention.

FIG. 8 is a schematic diagram showing an ideal condition of a crystal surface in the middle of a step-flow growth process in one embodiment.

FIG. 9 is a cross-sectional TEM image obtained by scanning the vicinity of a surface of an m-plane grown gallium nitride-based compound semiconductor in one embodiment.

FIGS. 10(a) and 10(b) are schematic diagrams showing the atomic structures of the m-plane of a gallium nitride-based compound semiconductor in one embodiment.

FIG. 11 is a graph illustrating the difference in growth rate dependence of the wavelength of an emission from an m-plane grown InGaN layer in one embodiment, which occurs due to the growth temperature.

FIG. 12 is a graph showing the results of calculation of the In mole fraction under the condition that only the Ga supply quantity is varying while the In supply quantity is constant.

FIG. 13 is a graph showing the difference in emission wavelength spectrum of the InGaN layer, which occurs due to the plane orientation.

FIG. 14 is a vertical cross-sectional view schematically showing the structure of a gallium nitride-based compound semiconductor light-emitting device in one embodiment of the present invention.

FIG. 15 is a schematic diagram showing the method of measuring the “growth temperature”.

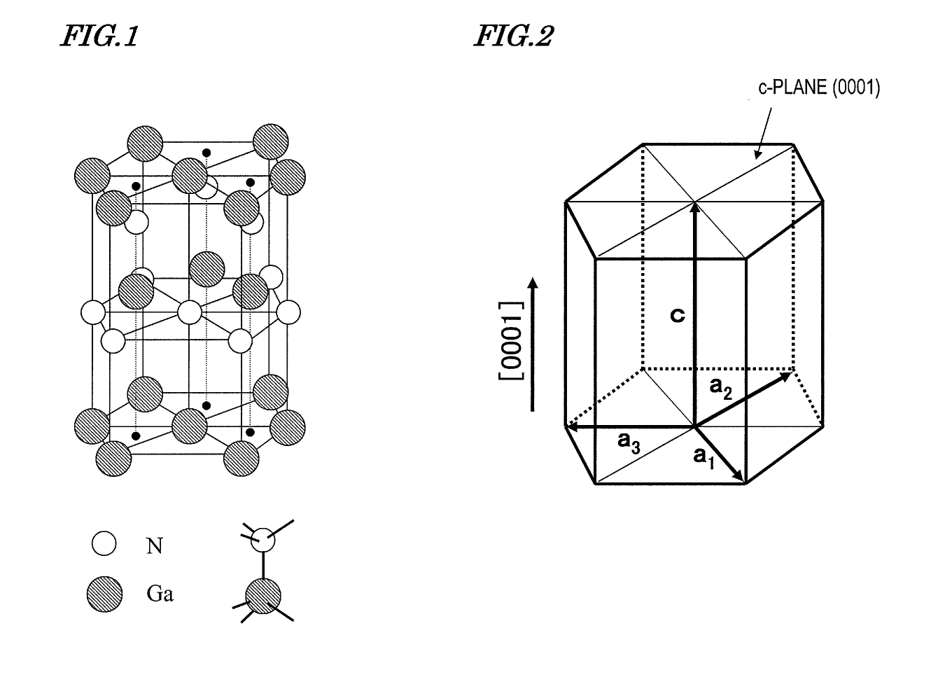

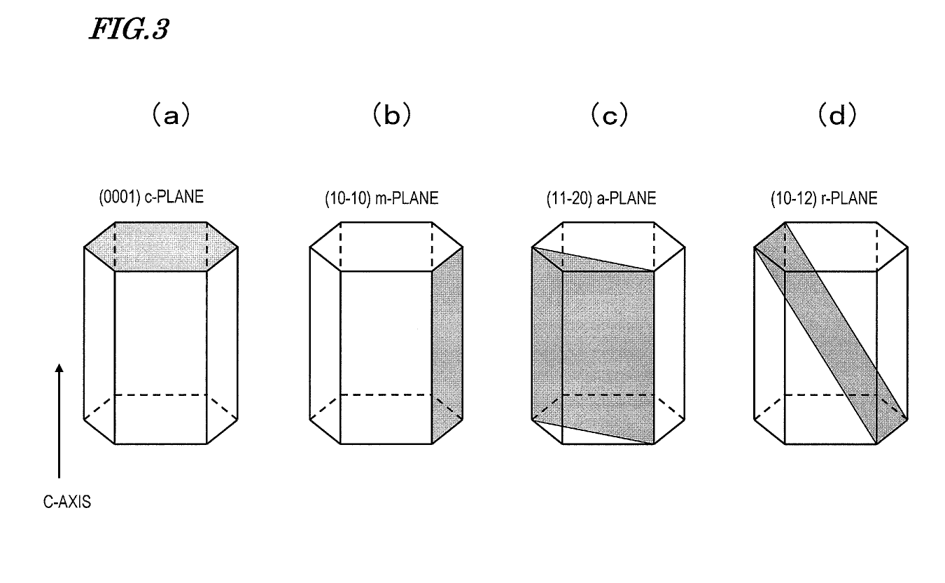

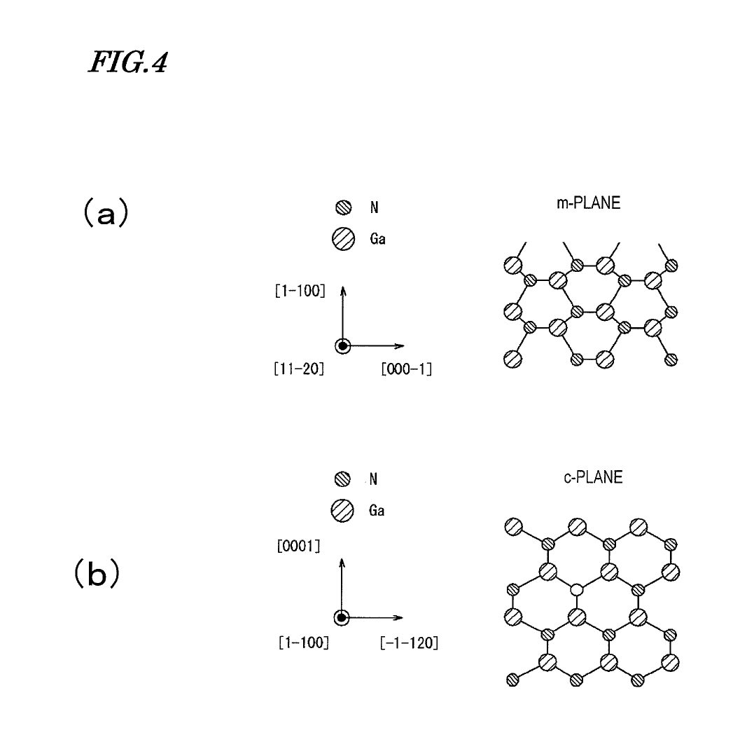

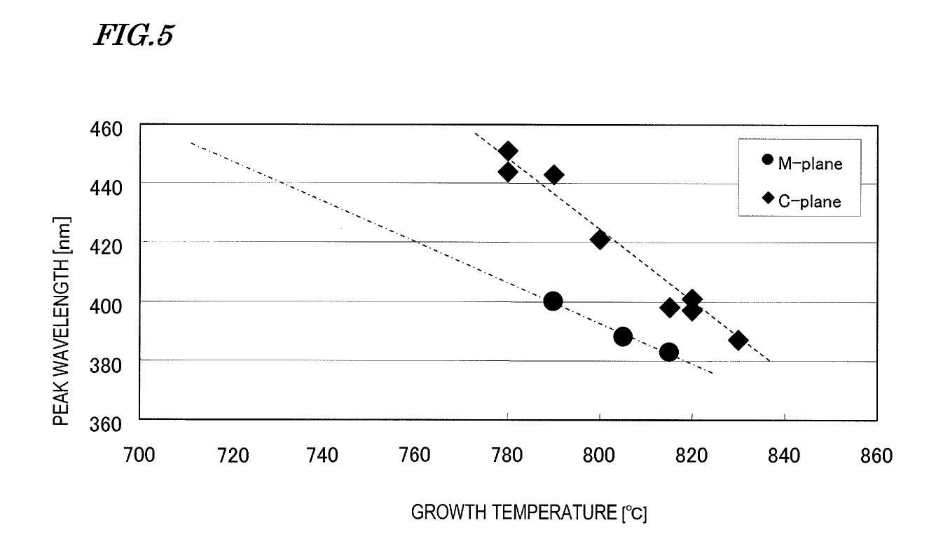

### DESCRIPTION OF EMBODIMENTS

In a preferred embodiment of the present invention, step (A) of heating a substrate in a reactor of a MOCVD apparatus and step (B) of supplying a source gas into the reactor and growing an m-plane InGaN layer of InₓGa₁₋ₓN (0<x<1) on the substrate are performed. In step (B), a gas containing an In source gas, a Ga source gas, and a N source gas is supplied into the reactor, and the growth rate of the m-plane InGaN layer is set so as to be not less than a predetermined value. The predetermined value is determined depending on an intended emission wavelength peak.

More specifically, in the case of growing an m-plane InGaN layer whose emission wavelength peak is not less than 500 nm, the growth rate is set to a value which is not less than 4.5 nm/min. In the case of growing an m-plane InGaN layer whose emission wavelength peak is in a range from 450 nm to 500 nm, the growth rate is set in a range from 3 nm/min to 10 nm/min. In the case of growing an m-plane InGaN layer whose emission wavelength peak is in a range from 425 nm to 475 nm, the growth rate is set to a value which is not less than 8 nm/min or set in a range from 4 nm/min to 5 nm/min. According to the present invention, as will be described later, the growth temperature is also regulated depending on an intended emission wavelength peak.

To increase the growth rate of the InGaN layer, it is necessary to increase the supply quantity of the Ga source gas as will be described later. Increasing the supply quantity of the Ga source gas under the condition that the supply quantity of the In source gas is constant means that the Ga supply proportion increases (whereas the In supply proportion decreases). Therefore, it is estimated that, when the supply quantity of the Ga source gas is increased, the In mole fraction x of the InₓGa₁₋ₓN (0<x<1) layer would decrease.

The “Ga supply proportion” is defined based on the molar supply flow rate (mol/min), i.e., the molar amount per minute, of the respective source gases of Ga and In that are Group III atoms supplied into the reactor during the growth of an InₓGa₁₋ₓN (0<x<1) layer. In this specification, the “Ga supply proportion” means the ratio of the supply rate of the Ga source gas to the total supply rate of the In source gas and the Ga source gas, which is shown in percentages. Therefore, the Ga supply proportion is expressed by the following formula:

$$\frac{[ Ga source gas ]}{[ In source gas ] + [ Ga source gas ]} \times 100 \% \qquad [ Formula 1 ]$$

where [Ga source gas] is the molar supply flow rate (mol/min), i.e., the molar amount per minute, of the supplied Ga source gas, and [In source gas] is the molar supply flow rate (mol/min), i.e., the molar amount per minute, of the supplied In source gas.

The In source gas is, for example, trimethylindium (TMI). The Ga source gas is, for example, trimethylgallium (TMG) or triethylgallium (TEG).

The In supply proportion is expressed by the following formula:

$$\frac{[ In source gas ]}{[ In source gas ] + [ Ga source gas ]} \times 100 \% \qquad [ Formula 2 ]$$

Note that the sum of the Ga supply proportion and the In supply proportion is 100%.

In this specification, for the sake of simplicity, the “supply rate” of a source gas is simply referred to as “supply quantity”. The supply rate of the Ga source gas (e.g., TMG) is simply referred to as “Ga supply quantity”. The supply rate of the In source gas (e.g., TMI) is simply referred to as “In supply quantity”.

In the prior art, in the case of performing a c-plane growth process of an InₓGa₁₋ₓN (0<x<1) layer by MOCVD, the factors that are usually regulated for controlling the In mole fraction x are “In supply proportion” and “growth temperature”. Formation of the InₓGa₁₋ₓN (0<x<1) layer by means of the c-plane growth is usually performed at as high a temperature as possible in order to prevent deterioration of crystallinity and decrease of the NH₃ decomposition efficiency as described above. In that case, In atoms are not smoothly incorporated into a crystal structure because they readily evaporate, and therefore, it is necessary to increase the In supply proportion as much as possible. Therefore, in the case of usual c-plane growth, the In supply proportion is set to about 90% or greater.

On the other hand, in the case of m-plane growth, the In incorporation efficiency is still lower as compared with c-plane growth. Therefore, even when the In supply quantity is increased for the purpose of increasing the In mole fraction, the In supply proportion, which is already as high as 90%, can be further raised by only a few percent, and therefore, the effect would be smaller than what is expected. The present inventors conducted examinations and found that increasing the In supply quantity would not produces a substantial effect in increasing the emission peak wavelength. Thus, in that situation, it is very difficult to realize, by means of the m-plane growth, InₓGa₁₋ₓN which is capable of emitting blue light (at about 450 nm) or green light (at 500 nm or longer).

The present inventors observed a phenomenon that, when the supply quantity of Ga rather than In is increased so that the In supply proportion decreases, the In incorporation efficiency rather increases, and arrived at completion of the present invention. Hereinafter, this phenomenon is described.

The present inventors analyzed behaviors of Ga and In during the course of a m-plane growth process and arrived at the new fact that, when the Ga supply quantity is increased so as to fall within an appropriate range, the In incorporation efficiency rather improves, even though the In supply proportion decreases. Increasing the Ga supply quantity is equivalent to increasing the growth rate of the InₓGa₁₋ₓN (0<x<1) layer. As will be described later, there is a linear relationship between the Ga supply quantity and the growth rate. Selectively increasing only the Ga supply quantity while the supply quantity of the In source gas is maintained constant means that the proportion of the In source gas in the source gas of the Group III atoms, i.e., the In supply proportion, decreases. It is very interesting phenomenon that, when the In supply proportion is decreased, the In incorporation efficiency rather improves.

In the prior art, the growth rate of the InₓGa₁₋ₓN layer which is to be used for the emission section of a light-emitting device is usually set to about 1 nm/min to 2 nm/min. On the contrary, according to the present invention, the growth rate is raised to an exceptionally high value as compared with the values of the prior art, typically, raised to a value not less than 4.5 nm/min.

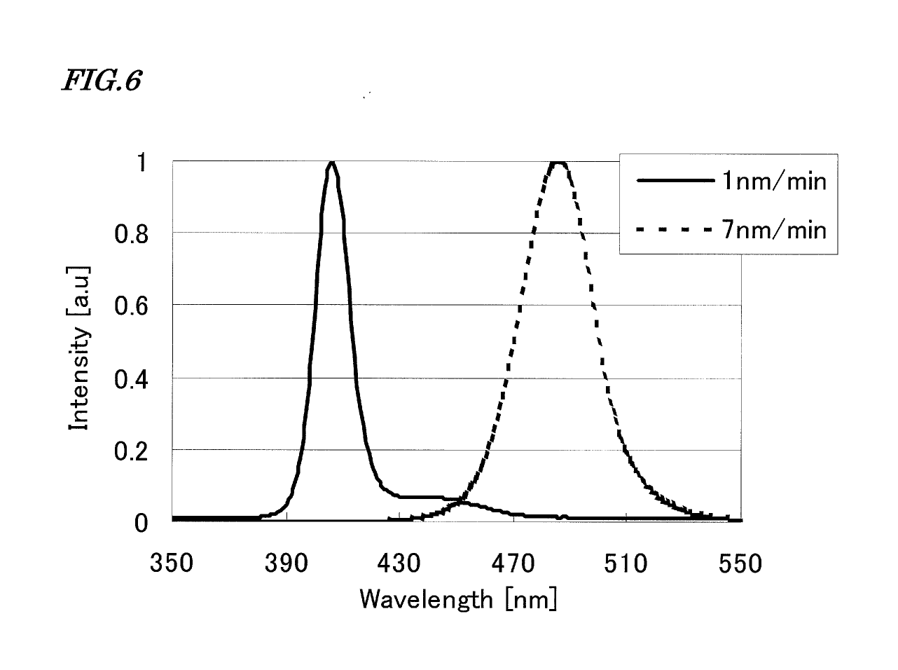

FIG. 6 shows the variation of the spectrum of an emission obtained from an InₓGa₁₋ₓN layer. Here, the growth rate of the InₓGa₁₋ₓN layer was raised from 1 nm/min to 7 nm/min by increasing the Ga supply quantity while the growth temperature was maintained at 780° C. and the In supply quantity was constant. In the graph of FIG. 6, the abscissa axis represents the wavelength (nm) of the emission obtained from the InₓGa₁₋ₓN layer, and the ordinate axis represents the intensity (arbitrary unit) of the emission. In the graph, the solid line represents an emission spectrum obtained from a sample where the growth rate was 1 nm/min, and the broken line represents an emission spectrum obtained from another sample where the growth rate was 7 nm/min.

It was confirmed from FIG. 6 that, by greatly increasing the Ga supply quantity, the emission wavelength was increased from 400 nm to 485 nm. In other words, it was discovered that, to raise the In mole fraction in the m-plane InₓGa₁₋ₓN layer, the “growth rate” that is regulated depending on the Ga supply quantity is a significant contributing factor. Note that the growth rate of the m-plane InₓGa₁₋ₓN layer is also referred to as “growing rate” or “film formation rate”. Throughout this specification, the unit of the growth rate is consistently “nm/min”.

Next, the relationship between the Ga supply quantity and the growth rate is described.

The Group III atoms of the InₓGa₁₋ₓN layer are Ga and In atoms. Usually, a sufficient amount of N atom, which is one of the Group V atoms, is supplied. Therefore, the growth rate of the InₓGa₁₋ₓN layer depends on the supply quantity of the Group III atoms. Here, the amount of N atoms is 10000 in the V/III ratio. For crystal growth of InGaN, the V/III ratio is preferably not less than 1000. Since, among the Group III atoms, In very readily evaporates in comparison to Ga, the growth rate of the entire crystal layer is substantially determined depending on the supply quantity of TMG or TEG that is supplied as the Ga source gas. In other words, the In supply quantity does not substantially contribute to the growth rate.

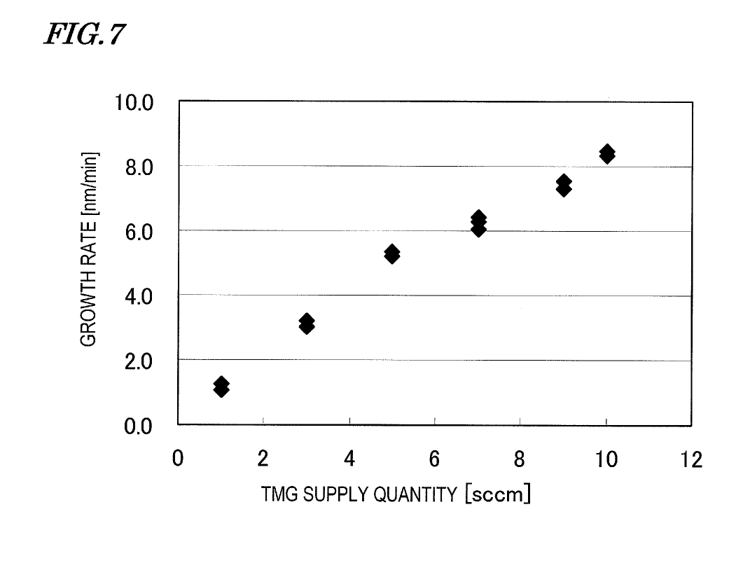

FIG. 7 is a graph which shows the relationship between the growth rate of the m-plane InₓGa₁₋ₓN layer and the supply quantity of TMG under the condition that TMG was supplied as the source of Ga. In the graph, the abscissa axis represents the supply quantity of TMG, and the ordinate axis represents the growth rate of the m-plane InₓGa₁₋ₓN layer. Here, the growth temperature was 770° C. to 790° C., and the supply quantity of TMI was 380 sccm (148.7 μmol/min). Note that the In supply quantity does not substantially contribute to the growth rate, and the tendency shown in FIG. 7 is not limited to the case where the In supply quantity is 380 sccm (148.7 μmol/min).

It is seen from FIG. 7 that the growth rate of the m-plane InₓGa₁₋ₓN layer can readily be controlled by regulating the Ga supply quantity. The data of FIG. 7 were obtained while the In supply quantity was fixed to a predetermined value. Thus, the increase of the Ga supply quantity means the decrease of the In supply proportion.

The reason why the In incorporation efficiency increases when the growth rate of the InGaN layer, i.e., the Ga supply quantity, is increased can be explained based on the behavior of Ga and In in a step-flow growth process of the crystal. Hereinafter, the knowledge obtained by the present inventors about the relationship between the Ga supply quantity and the In incorporation efficiency in a growth process of the m-plane InₓGa₁₋ₓN layer will be described.

In general, although not limited to the gallium nitride-based compound semiconductor, an ideal surface of a growing crystal is formed by periodic alternation of a flat area called “terrace”, which is relatively large on the atomic level, and a vertical wall called “step”, which has a height of a single atomic layer, so that the surface of the growing crystal has a shape which schematically looks like a stairs.

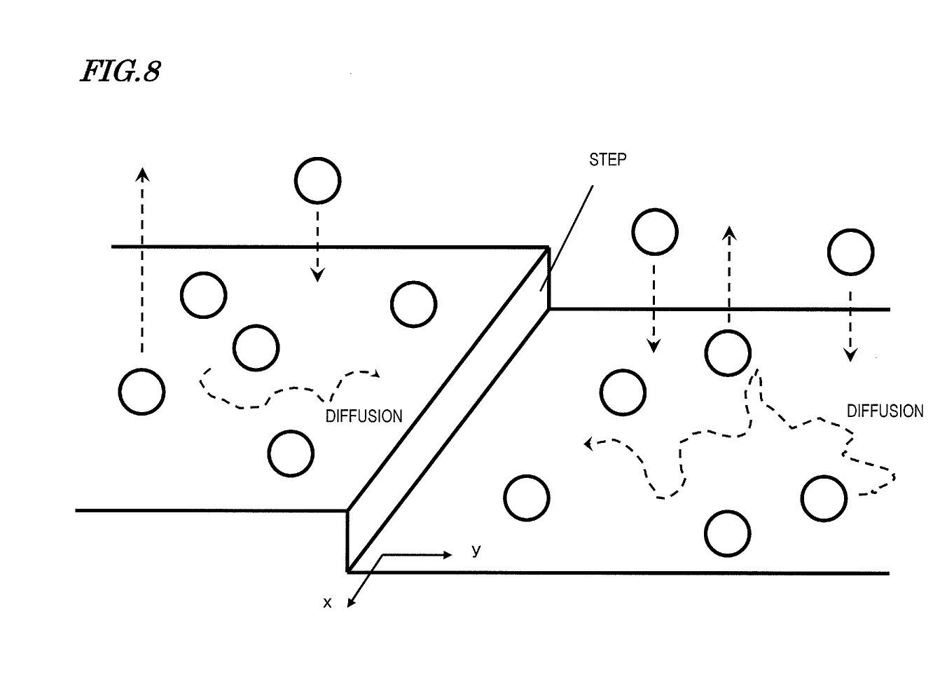

FIG. 8 is a perspective view schematically showing the condition of a crystal surface during crystal growth. In FIG. 8, one step extending in the x-axis direction and terraces are shown. An actual crystal surface has many steps and terraces. Open circles (◯) in the diagram schematically represent Ga and In atoms.

Atoms of Ga, In, etc., that are incident on a surface of a growing crystal (growing plane) can move around by random diffusion over the terraces, even after once adsorbed by the terraces, because the atoms have kinetic energy. The atoms in such a condition cannot be recognized as being incorporated into the crystal (or “solidified”). It is because, in the course of diffusion, the atoms may evaporate back into the gas phase.

Some of the atoms which happen to arrive at the step in the course of random diffusion stop diffusing and settle down there. These atoms can be recognized as having been solidified. It is because there are many dangling bonds at the position of the step as compared with the terraces that have nothing on them. Once atoms reach there, the number of bonds increases so that the atoms settle into a stable condition. In other words, the step serves as the site of incorporation of atoms. Conversely, atoms cannot be solidified without reaching the position of the step.

Atoms diffuse to reach the position of the step one after another and are continuously incorporated into the crystal, so that the step advances. Repetition of this process realizes crystal growth in a layer by layer fashion. This is referred to as “step-flow growth” of the crystal.

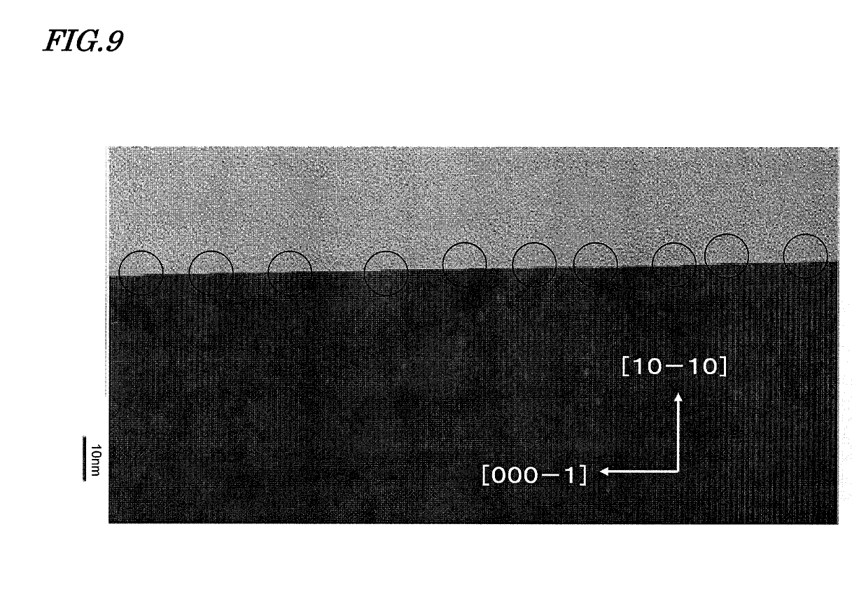

The present inventors confirmed that the surface of an InGaN layer in the middle of an m-plane growth process have steps at a generally periodic interval, each of the steps having a height of a single atomic layer. FIG. 9 is a cross-sectional TEM image of an m-plane InGaN layer. It can be seen that the growing plane of the m-plane InGaN layer has many steps. Therefore, it is inferred that the above-described principle of the step-flow growth also applies to the m-plane growth of the gallium nitride-based compound semiconductor.

In the case of manufacturing the gallium nitride-based compound semiconductor, the V/III ratio, which is the supply quantity ratio between the Group III atoms and the Group V atoms, is typically set to a value that is at least not less than 10³. Therefore, N atoms, which are the Group V atoms, abundantly exist as compared with the Group III atoms. Thus, it is estimated that, at the crystal surface of the growing gallium nitride-based compound semiconductor, N atoms frequently repeat bonding with and separation from the Group III atoms.

As seen from FIG. 7, the growth rate of the crystal is substantially determined depending only on the Ga supply quantity. Therefore, it can be said that the Group III atoms, particularly Ga atom, determine the rate of the crystal growth of the gallium nitride-based compound semiconductor. In other words, N atoms abundantly exist at the crystal surface.

Thus, arrival of Ga atoms at the position of the step is very important for advancement of the position of the step, i.e., advancement of crystal growth. In the case of growth of the InGaN layer, if it is possible to estimate the proportion of In atoms which arrive at the step and are stably incorporated into the crystal in an environment that contains a large majority of Ga atoms, the In mole fraction will be determined.

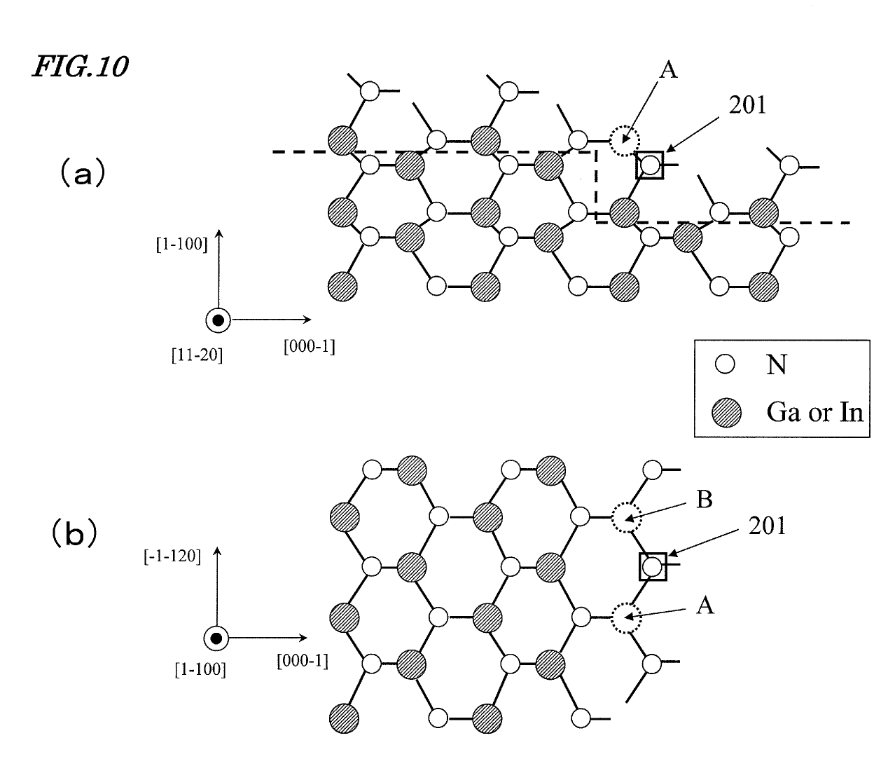

The present inventors considered N atoms at the position of the step and set up a hypothesis. This hypothesis will be described with reference to FIG. 10.

FIG. 10(a) is a schematic cross-sectional view showing the crystal structure of an m-plane gallium nitride on the atomic level. FIG. 10(b) is a schematic top view of the crystal structure. In FIG. 10(a), the broken line represents a representative step. In FIG. 10(b), atoms belonging to a terrace on the lower side of the step are not shown.

Now, suppose that an In atom arrives at point A which is at the position of the step. A N atom 201, which is at a site where it is to bond with a Group III atom arriving at point A, has only a single bond with a Group III atom which is already inside the crystal, and is therefore very unstable. However, when the In atom arrives at point A, the stability of the N atom 201 is improved because one of unoccupied dangling bonds forms a bond with the In atom arriving at point A.

However, the bond energy between the In atom and the N atom (1.93 eV) is smaller than the bond energy between the Ga atom and the N atom (2.24 eV). Thus, it is estimated that, if an atom which arrives at point A to bond itself with the N atom 201 is a Ga atom, the stability of the N atom 201 will greatly increase, so that the Ga atom will also stably reside there. However, if an atom which arrives at point A is an In atom, a new bond between the In atom and the N atom 201 will not greatly contribute to improvement of the stability of the N atom 201. Therefore, the N atom 201 will remain unstable and go back into the gas phase within a very short period of time due to thermal fluctuation. Accordingly, the In atom arriving at point A may also go away, rather than being incorporated into the crystal.

However, if at point B which is adjacent to point A along the step there is already another Ga atom which has arrived there earlier, the N atom 201 already has two bonds with Gs atoms and therefore can stably reside there. When an In atom arrives at point A in that situation, the N atom 201 rarely leaves the site to evaporate into the gas phase because it already has sufficient stability.

As a result, the probability increases that the In atom arriving at point A will stably reside there. If a Ga atom arrives at adjacent point B immediately after the arrival of the In atom at point A, the stability of the N atom 201 will improve, and as a result, the In atom will stably reside there.

To realize stable incorporation of In atoms into the crystal at the position of the step, it is necessary to improve the stability of intervening N atoms, which are Group V atoms, at the position of the step. Thus, a hypothesis can be set up that, to this end, increasing the number of Ga atoms arriving at the step, i.e., increasing the density of Ga atoms at the position of the step, is effective.

The correctness of the above hypothesis was confirmed by both experiment and simulation (calculation).

(Verification by Experiment)

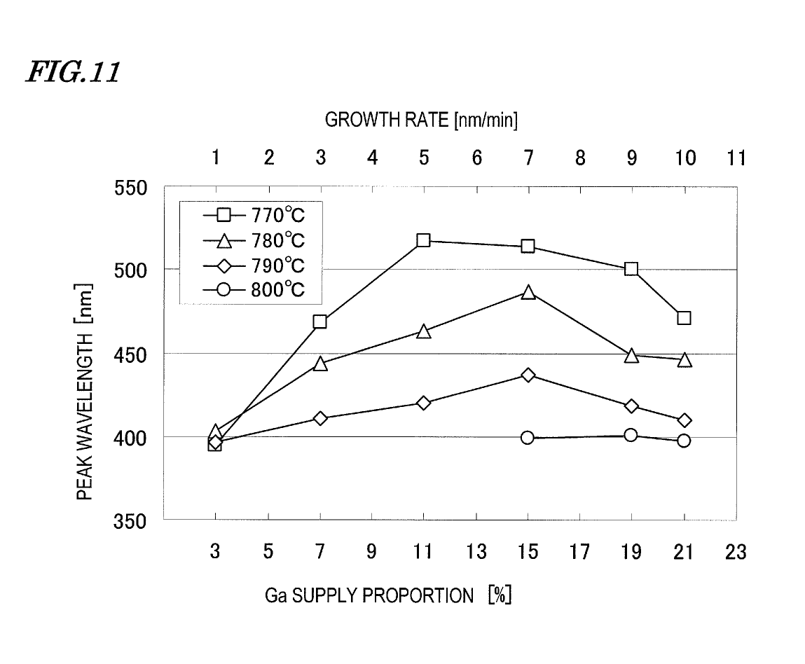

The relationship between the experimentally-obtained emission wavelength of the m-plane InₓGa₁₋ₓN (0<x<1) layer and the Ga supply quantity (growth rate) is now described with reference to FIG. 11. Note that the light-emitting layer is formed by alternately depositing a GaN barrier layer (3 nm) and an InₓGa₁₋ₓN well layer (7 nm) in three cycles.

FIG. 11 is a graph showing the relationship of the wavelength of emissions from m-plane InₓGa₁₋ₓN layers, which were formed at different growth temperatures under the condition that the In supply quantity was constant at 380 sccm (148.7 μmol/min), to the growth rate and the Ga supply proportion. The ordinate axis of the graph represents the peak wavelength of the emission. One of the abscissa axes at the bottom of the graph represents the Ga supply proportion under the condition that the In supply quantity is constant at 380 sccm (148.7 μmol/min). The other abscissa axis at the top of the graph represents the growth rate of the InₓGa₁₋ₓN layer.

Next, the relationship between the growth rate (top abscissa axis) and the Ga supply proportion (bottom abscissa axis) is described. For example, when the growth rate of the InₓGa₁₋ₓN layer is 5 nm/min, the Ga supply proportion corresponds to 11%. This relationship holds true only when the In supply quantity is set to 380 sccm (148.7 μmol/min). That is, if the In supply quantity is set to a different value, setting the growth rate to 5 nm/min would not result in that the Ga supply proportion is 11%. Note that the growth rate is not affected by the In supply quantity but depends on the Ga supply quantity, and therefore, the feature of the present invention can be more clearly expressed by comparison with the Ga supply proportion. Here, the growth temperature is 770° C., 780° C., 790° C., or 800° C.

The values of the emission peak wavelength which are described in this specification, such as in FIG. 11, were all obtained by PL (photoluminescence) measurement at room temperature with the use of a 325 nm He—Cd laser as an excitation light source. However, substantially equal emission peak wavelengths would be obtained by EL (electroluminescence) measurement.

Table 2 to Table 5 below show the relationships between the growth rates shown in FIG. 11 and the peak wavelengths for respective growth temperatures.

TABLE 2

| | Growth Temperature 770° C. | | | | | |
|---|---|---|---|---|---|---|
| | Growth Rate (Ga Supply Proportion) | | | | | |
| | 1 nm/min | 3 nm/min | 5 nm/min | 7 nm/min | 9 nm/min | 10 nm/min |
| | (3%) | (7%) | (11%) | (15%) | (19%) | (21%) |
| Peak Wavelength (nm) | 395 | 468 | 517 | 514 | 500 | 471 |

TABLE 3

| | Growth Temperature 780° C. | | | | | |
|---|---|---|---|---|---|---|
| | Growth Rate (Ga Supply Proportion) | | | | | |
| | 1 nm/min | 3 nm/min | 5 nm/min | 7 nm/min | 9 nm/min | 10 nm/min |
| | (3%) | (7%) | (11%) | (15%) | (19%) | (21%) |
| Peak Wavelength (nm) | 403 | 444 | 463 | 487 | 449 | 446 |

TABLE 4

| | Growth Temperature 790° C. | | | | | |
|---|---|---|---|---|---|---|
| | Growth Rate (Ga Supply Proportion) | | | | | |
| | 1 nm/min | 3 nm/min | 5 nm/min | 7 nm/min | 9 nm/min | 10 nm/min |
| | (3%) | (7%) | (11%) | (15%) | (19%) | (21%) |
| Peak Wavelength (nm) | 396 | 411 | 420 | 437 | 418 | 410 |

TABLE 5

| | Growth Temperature 800° C. | | | | | |
|---|---|---|---|---|---|---|
| | Growth Rate (Ga Supply Proportion) | | | | | |
| | 1 nm/min | 3 nm/min | 5 nm/min | 7 nm/min | 9 nm/min | 10 nm/min |
| | (3%) | (7%) | (11%) | (15%) | (19%) | (21%) |
| Peak Wavelength (nm) | | | | 399 | 401 | 397 |

As previously described with reference to FIG. 7, the growth rate of the InₓGa₁₋ₓN layer linearly increases as the Ga supply quantity increases.

It is confirmed from the graph of FIG. 11 that, when the growth temperature is lower than 800° C., at either temperature, there is a range in which as the growth rate (the Ga supply proportion under the condition that the In supply quantity is constant) increases, the peak wavelength of an emission becomes longer. The increase of the wavelength of the emission means an increase of the In mole fraction. Since the In supply quantity is constant, the increase of the growth rate is equivalent to the decrease of the In supply proportion. It is seen that the In incorporation efficiency increases as the In supply proportion decreases. This result confirms that the above hypothesis is correct.

The degree of the increase of the wavelength which occurs as the growth rate increases varies depending on the growth temperature. When the growth rate is 1 nm/min (or when the Ga supply proportion is 3%), generally equivalent emissions near 400 nm are obtained at 770° C., 780° C. and 790° C. When the growth rate is 5 nm/min (or when the Ga supply proportion is 11%), the emission wavelength obtained at the growth temperature of 790° C. is about 420 nm. However, when the growth temperature was decreased to 770° C., the wavelength of the emission increased to about 520 nm, so that the emission exhibited a bright green color to a human eye. In achieving a longer wavelength by increasing the growth rate, decreasing the growth temperature is effective.

(Verification by Simulation)

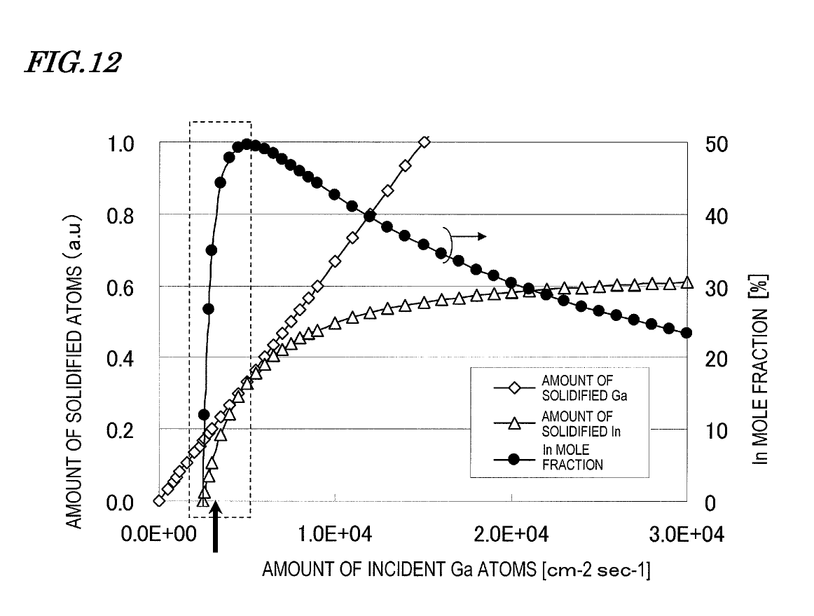

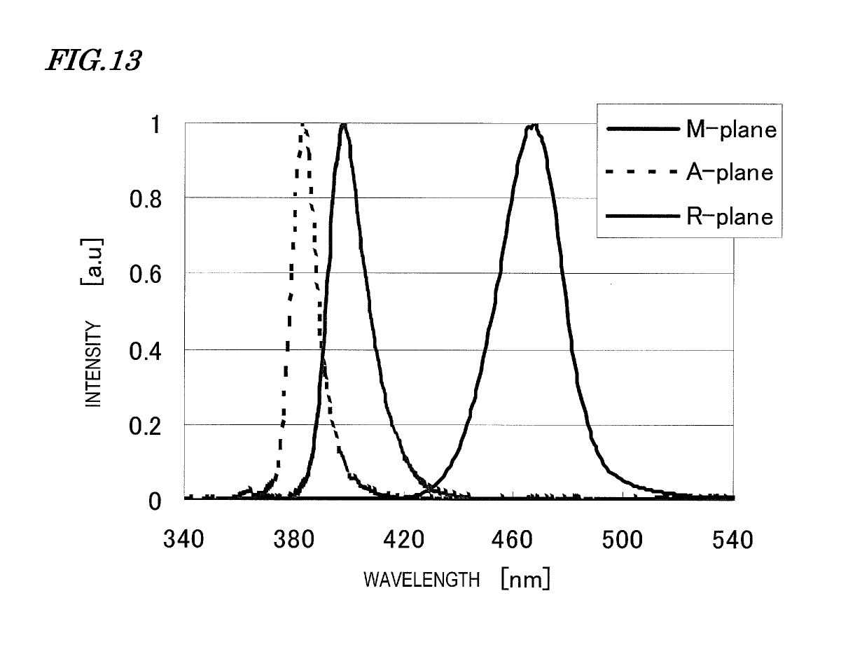

FIG. 12 is a graph showing the relationships between the amounts of respective solidified atoms and the Ga supply quantity, which were obtained by simulation. The amount of solidified atoms represents the number of atoms which are absorbed and fixed to a step in a growing plane so as to be incorporated into the crystal per unit time. Details of the formulae and the calculation conditions used for running this simulation will be described later.

In the graph of FIG. 12, the abscissa axis represents the amount of Ga atoms which are incident on the growing plane (the amount being proportional to the Ga supply quantity). In the calculation, only the Ga supply quantity is increased while the In supply quantity (the amount of In atoms which are incident on the growing plane) is maintained constant (1×10⁵ cm⁻²sec⁻¹). Since the In supply quantity is maintained constant, when the Ga supply quantity is increased, the In supply proportion inevitably decreases.

In the graph of FIG. 12, the left ordinate axis represents the amount of respective solidified atoms (arbitrary unit), and the right ordinate axis represents the In mole fraction. The In mole fraction means the proportion of In atoms to the total Group III atoms incorporated into the crystal (In mole fraction x), which is indicated by solid circles in the graph. The number of In atoms incorporated into the crystal (the amount of solidified In atoms) per unit time is indicated by open triangles Δ, and the number of incorporated Ga atoms (the amount of solidified Ga atoms) is indicated by open diamonds ⋄.

As seen from FIG. 12, the amount of incident Ga atoms increases, the amount of solidified Ga atoms (⋄) increases, and the amount of solidified In atoms (Δ) also increases. The simulation result that the amount of solidified In atoms increases when the In supply quantity is constant and the Ga supply quantity increases confirms that the above hypothesis is correct.

It is seen that, in the range of the graph which is enclosed by the broken line, the In mole fraction enormously increases as the Ga supply quantity increases. In this range, the In mole fraction is sensitive to the variation of the Ga supply quantity.

In the prior art, it is common knowledge that the In incorporation efficiency is low so that it is difficult to increase the In mole fraction. This is because, in many of the existing manufacture processes currently in practice, the crystal growth is performed with the Ga supply quantity being at a value lower than the value indicated by the arrow in FIG. 12 (about 3000 cm⁻²sec⁻¹).

Many of the parameters in the calculation formula which will be described below have unknown physical property values. Therefore, in obtaining the results shown in FIG. 12, known physical property values of a substance which is similar to the gallium nitride, or arbitrarily assumed values which are expected not to be largely different from the actual physical property values, were used as substitutes for the unknown physical property values. Thus, the results of FIG. 12 lack reliability in terms of strict quantification but are sufficiently reliable for an overview of a qualitative tendency.

Again, refer to FIG. 11.

A lot of knowledge can be derived from the experimental results shown in FIG. 11. For example, it is possible to select crystal growth conditions which are suitable to achievement of an intended emission peak wavelength. Hereinafter, this aspect is described in detail.

At either of the growth temperatures, 770° C., 780° C., and 790° C., there is a tendency that the emission wavelength is maximized in the range of the growth rate from 5 nm/min to 7 nm/min (in the range of the Ga supply proportion from 11% to 15%). When the Ga supply quantity is further increased to raise the growth rate (the Ga supply proportion under the condition that the In supply quantity is constant), this wavelength increasing tendency declines or, on the contrary, the wavelength decreases. This result confirms the tendency obtained by the calculation shown in FIG. 12. Therefore, there is a range of the growth rate (the Ga supply proportion under the condition that the In supply quantity is constant) which is effective in increasing the In mole fraction.

When the growth temperature is 800° C., the emission wavelength rarely exhibits dependence on the growth rate (the Ga supply proportion under the condition that the In supply quantity is constant). Therefore, it is seen that there is a range of the growth temperature in which the growth rate (the Ga supply proportion under the condition that the In supply quantity is constant) is a contributing factor in increasing the In mole fraction. As seen from FIG. 11, the growth temperature is preferably lower than 800° C. (e.g., 795° C. or lower).

According to the graph of FIG. 11, in order to realize green emission (at the wavelength of 500 nm or longer), the InGaN layer is desirably deposited with the growth temperature being set lower than 780° C. (preferably, in the range from 700° C. to 775° C.) and with the supply of the Group III source material being regulated such that the growth rate is between 4.5 nm/min and 10 nm/min. In other words, when the In supply quantity is set to 380 sccm (148.7 μmol/min), the InGaN layer is desirably deposited with the supply of the Group III source material being regulated such that the Ga supply proportion is in the range from 10% to 21%.

When the growth rate is 4.5 nm/min, a wavelength of 500 nm or longer can be realized by setting the growth temperature to about 772° C. or lower. When the growth rate is 10 nm/min, a wavelength of 500 nm or longer can be realized by setting the growth temperature to about 750° C. or lower. On the other hand, when the growth temperature is 770° C., a wavelength of 500 nm or longer can be realized by setting the growth rate in the range from 4.5 nm/min to 9 nm/min.

To realize a wavelength in the range from 450 nm to 500 nm (typically, near 475 nm), the InGaN layer is desirably deposited with the growth temperature being maintained near 780° C. (in the range from 775° C. to 785° C.) and with the supply of the Group III source material being regulated such that the growth rate is between 3 nm/min and 10 nm/min. In other words, when the In supply quantity is set to 380 sccm (148.7 μmol/min), the InGaN layer is desirably deposited with the supply of the Group III source material being regulated such that the Ga supply proportion is between 7% and 21%.

To realize a wavelength in the range from 425 nm to 475 nm (typically, near 450 nm), the InGaN layer is desirably deposited with the growth temperature being maintained in the range from 770° C. to 790° C. and with the supply of the Group III source material being regulated such that the growth rate is between 4 nm/min and 5 nm/min or not less than 8 nm/min. In other words, when the In supply quantity is set to 380 sccm (148.7 μmol/min), the InGaN layer is desirably deposited with the supply of the Group III source material being regulated such that the Ga supply proportion is between 9% and 11% or not less than 17%.

When the wavelength is 500 nm or shorter, although not intended to increase the amount of incorporated In atoms, it is effective in improving the quality of the InGaN crystal. High crystal quality means a small number of crystal defects and, accordingly, high emission characteristics (efficiency). Higher crystal quality enables an emission at a lower voltage. If the voltage is constant, higher crystal quality enables a greater quantity of emission.

According to the research conducted by the present inventors, the present invention enables formation of an m-plane InₓGa₁₋ₓN (x≦0.45) crystal which is capable of emitting at wavelengths up to near 550 nm. When x=0.45, this crystal can be realized under the conditions that the growth temperature is 730° C. to 740° C. (optimally, 730° C.) and the growth rate is 6 nm/min to 8 nm/min (optimally, 7 nm/min). Note that the In supply quantity is 380 sccm (148.7 μmol/min).

In forming an m-plane (x>0.45) crystal which is capable of emitting at a wavelength longer than 550 nm, it is necessary to decrease the growth temperature to be lower than 700° C., even under the condition that the growth rate is 4.5 nm/min or higher, which is recognized as being optimum according to the present invention. Many of the samples prepared under the condition that the growth temperature is lower than 700° C. have a metallic hue. It is estimated that such samples have an increased non-emission center. Since the emission intensity is extremely low, it is difficult to detect a clear wavelength peak.

In the (0001) c-plane growth of the prior art, the quantum confinement Stark effect is normegligible. Therefore, it is difficult to increase the growth rate of the InGaN well layer that will be part of the emission section. It is because, to cancel the quantum confinement Stark effect as much as possible, it is necessary to decrease the thickness of the InGaN well layer to a certain thickness, typically 5 nm or smaller. Increasing the growth rate inevitably increases the variation relative to the thickness of the InGaN well layer, so that regions in which the quantum confinement Stark effect is normegligible locally occur inside the substrate. As a result, the emission efficiency significantly deteriorates, and the manufacturing yield decreases.

However, the m-plane growth does not cause the quantum confinement Stark effect and, therefore, does not require decreasing the thickness of the InGaN well layer. Thus, the growth rate can be increased without any hindrance.

Since the m-plane growth does not cause the quantum confinement Stark effect, the expectation of improvement in efficiency grows as the thickness of the InₓGa₁₋ₓN (0<x<1) well layer increases. This is because it is possible to increase the number of carriers which can be captured by the InₓGa₁₋ₓN layer. Specifically, the thickness of the InₓGa₁₋ₓN well layer that is formed by means of the m-plane growth is preferably set in the range from 6 nm to 20 nm. Therefore, a higher growth rate of the m-plane grown InₓGa₁₋ₓN (0<x<1) layer is rather preferred. It can be said that the present invention is also advantageous in terms of production efficiency.

The present inventors prepared samples by simultaneously depositing InGaN layers on the (11-20) a-plane, which is another example of the non-polar plane other than the (10-10) m-plane, and on the (10-12) r-plane, which is a typical semi-polar plane, as well as on the m-plane, under the conditions that the growth temperature is 785° C. and the growth rate is 7 nm/min. FIG. 13 shows the emission wavelength spectrums of the prepared samples. The m-plane growth sample exhibited a peak value near 470 nm, whereas the other plane orientation samples only achieved a wavelength near 400 nm at best. This result confirms that the inventive concept of increasing the In mole fraction in the InGaN layer is highly effective for the (10-10) m-plane. It can be said that the present invention provides a technique which is special to the m-plane.

The present inventors also found that, if the means of the present invention is not used, increasing the In mole fraction in the InGaN layer grown on the m-plane, i.e., increasing the wavelength, is extremely difficult to achieve. For example, in the case where only the growth temperature is controlled in order to increase the wavelength of the emission from the InGaN layer while the growth rate is maintained at 1 nm/min, which is typically used in the c-plane growth of the prior art, the substrate is tinted with a metallic hue in not a few portions. In such portions, the emission spectrum cannot be detected as a result.

According to the research conducted by the present inventors, when the increase of the wavelength is realized only by means of decreasing the temperature, the portions of the substrate tinted with a metallic hue rarely occur in the wavelength range shorter than about 500 nm. When a still longer wavelength is intended, there is such a tendency that metallic hue portions occur across a relatively large area. This is probably because, when a wavelength of 500 nm or longer is realized only by means of decreasing the temperature, the growth temperature typically decreases below 700° C., so that the decomposition efficiency of NH₃ significantly deteriorates.

However, the method of the present invention is free from such a disadvantage because an InGaN layer which is capable of emitting at the wavelength of 500 nm or longer can be formed without greatly decreasing the temperature. Thus, the present invention is almost indispensable for deriving an emission wavelength of at least 500 nm from the InGaN layer deposited by means of the m-plane growth.

In almost all the experiments described in this specification, the In supply quantity is fixed at 380 sccm (148.7 μmol/min). However, the absolute value of the In supply quantity is not essential in the present invention. Since the In supply proportion is already sufficiently large, the influence of the variation of the In supply quantity on the increase of the wavelength is extremely small. The essential part of the present invention is that, when the growth rate of the InGaN layer is increased by increasing the Ga supply quantity, the In mole fraction of the InGaN layer improves even though the In supply proportion decreases.

### Embodiment

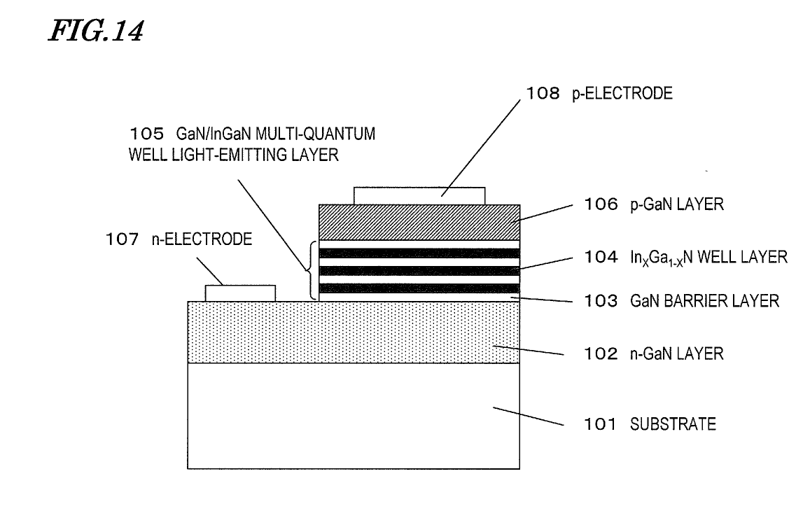

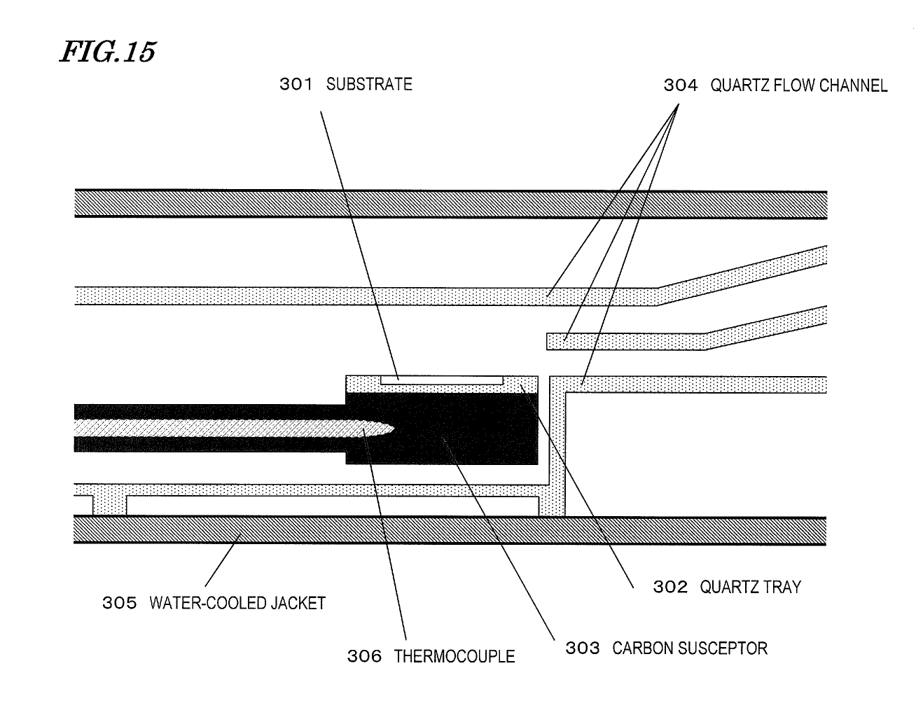

Hereinafter, an embodiment of fabrication of a semiconductor light-emitting device which is performed according to a gallium nitride-based compound semiconductor formation method of the present invention is described with reference to FIG. 14.

A substrate 101 for crystal growth which is used in the present embodiment is capable of growth of (10-10) m-plane gallium nitride (GaN). Most preferably, it is a free-standing substrate of gallium nitride itself whose principal surface is an m-plane, but may be a substrate of silicon carbide (SiC) whose lattice constant is close to that of gallium nitride and which has a 4H or 6H structure with an m-plane principal surface. Alternatively, a sapphire substrate that also has an m-plane principal surface may be used. However, if a material that is different from the gallium nitride-based compound semiconductor is used for the substrate, an appropriate spacer layer or buffer layer is inserted between the substrate and a gallium nitride-based compound semiconductor layer which is to be deposited thereon.

The actual m-plane does not always have to be a plane that is exactly parallel to an m-plane but may be slightly tilted from the m-plane by 0±1 degree.

Deposition of the gallium nitride-based compound semiconductor, represented by the InₓGa₁₋ₓN (0<x<1) layer, is realized by MOCVD (Metal Organic Chemical Vapor Deposition). Firstly, the substrate 101 is washed with a buffered hydrofluoric acid solution (BHF) and is thereafter sufficiently washed with water and dried. After having been washed, the substrate 101 is kept away from air as much as possible and placed in a reactor of a MOCVD apparatus. Thereafter, the substrate is heated to 850° C. while ammonium (NH₃) is supplied as the nitrogen source, and the substrate surface is cleaned.

Then, trimethylgallium (TMG) or triethylgallium (TEG) and silane (SiH₄) are supplied, and the substrate is heated to about 1100° C., whereby an n-GaN layer 102 is deposited. Silane is a source gas for supplying silicon (Si) that is used as an n-type dopant.

Then, the supply of SiH₄ is stopped, and the substrate is cooled to a temperature lower than 800° C., whereby a GaN barrier layer 103 is deposited. Then, supply of trimethylindium (TMI) is started, whereby an InₓGa₁₋ₓN (0<x<1) well layer 104 is deposited. The GaN barrier layer 103 and the InₓGa₁₋ₓN (0<x<1) well layer 104 are alternately deposited in three or more cycles, whereby a GaN/InGaN multi-quantum well light-emitting layer 105, which will function as the emission section, is formed. The reason for the three or more cycles is that, as the number of InₓGa₁₋ₓN (0<x<1) well layers 104 increases, the volume for capturing carriers that contribute to radiative recombination increases, so that the efficiency of the device improves.

After the formation of the GaN/InGaN multi-quantum well light-emitting layer 105, the supply of TMI is stopped, and the growth temperature is increased to 1000° C. And, bis-cyclopentadienyl magnesium (Cp₂Mg) which is the source of Mg that is used as a p-type dopant is supplied, whereby a p-GaN layer 106 is deposited.

After the substrate is removed out of the reactor, only predetermined regions of the p-GaN layer 106 and the GaN/InGaN multi-quantum well light-emitting layer 105 are removed, e.g., etched away, by photolithography, or the like, such that part of the n-GaN layer 102 is exposed. On the exposed part of the n-GaN layer 102, an n-type electrode is formed of, for example, Ti/Al. Meanwhile, in a predetermined region of the surface of the p-GaN layer 106, a p-type electrode is formed of, for example, Ni/Au.

Through the above process, respective ones of the n-type and p-type carriers can be implanted. Thus, a light-emitting device can be fabricated in which an emission at a desired wavelength is obtained from the GaN/InGaN multi-quantum well light-emitting layer 105 that is formed according to the fabrication method of the present invention.

The values of the In mole fraction for realizing the respective wavelengths are generally calculated as shown below. Note that the calculation results of the In mole fraction may have an error depending on the physical property values, such as the elastic constant, and the thickness of the well layer. Thus, the relationship between the emission wavelengths to be realized and the In mole fraction is not limited to the following example.

410 nm→In mole fraction: 8-12%

430 nm→In mole fraction: 13-17%

450 nm→In mole fraction: 18-22%

475 nm→In mole fraction: 24-28%

500 nm→In mole fraction: 30% or more

Next, a method of measuring the “growth temperature” in this specification is described with reference to FIG. 15. FIG. 15 is a diagram showing a cross-sectional structure of the reactor of an MOCVD apparatus used in the experiment of the present invention.

In the shown reactor, a substrate 301 is seated in a receptacle hollow of a quartz tray 302. The quartz tray 302 is placed on a carbon susceptor 303 in which a thermocouple 306 is buried. The carbon susceptor 303 is installed in a quartz flow channel 304. The quartz flow channel 304 is provided inside a water-cooled jacket 305.

The carbon susceptor 303 is heated by an unshown coil surrounding the water-cooled jacket 305 according to an RF induction heating method. The substrate 301 is heated by means of heat conduction from the carbon susceptor 303.

In this specification, the “growth temperature” is a temperature measured by the thermocouple 306. This temperature is a temperature of the carbon susceptor 303 that is a direct heat source for the substrate 301. The carbon susceptor 303 is in direct thermal contact with the substrate 301. Therefore, the temperature measured by the thermocouple 306 is approximately equal to the temperature of the substrate 301 during a growing process of the light-emitting layer.

The source gas and the doping gas are supplied from the outside of the reactor and guided through paths defined by the quartz flow channel to arrive at a region near the substrate 301.

The gallium nitride-based compound semiconductor formation method of the present invention may be suitably performed even when an apparatus other than the apparatus that has the above-described configuration. In performing the formation method of the present invention, the method of heating the substrate and the method of measuring the substrate temperature are not limited to the above-described methods.

(Simulation)

The calculation formulae and the calculation conditions used in the simulation illustrated in FIG. 12 are described below.

The present inventors calculated the density distribution of Ga and In atoms moving around by diffusion over the terraces. By calculating the gradient of the calculated density distribution at the position of a step, the numbers of Ga and In atoms incorporated into the crystal per unit time at the position of the step can be obtained.

Here, it is assumed that the terraces have such a structure that the step is parallel to the x-axis direction as shown in FIG. 8. Actually, each of the steps in the growing plane extends in one direction, and the above assumption accords well with an actual growing plane. Under that assumption, either of the density of Ga atoms and the density of In atoms lying on the terrace must be uniform along the x-axis direction and have varying distributions only along the y-axis direction. Therefore, the density of Ga atoms on the terrace does not depend on the coordinate x but is expressed by C^{Ga}(y) that is a function of the coordinate y. Likewise, the density of the In atoms is expressed by C^{In}(y) that is a function of the coordinate y. C^{Ga} (y) and C^{In} (y) can be simply expressed as C^{Ga} and C^{In}.

C^{Ga} and C^{In} meet the diffusion equation of Formula 3 and the diffusion equation of Formula 4, respectively, which are shown below. These diffusion equations (differential equations) are solved under predetermined boundary conditions, whereby C^{Ga} and C^{In} can be obtained.

$$\begin{matrix}\frac{\partial {C}^{Ga}}{\partial t} = {D}_{S}^{Ga} \frac{{\partial }^{2} {C}^{Ga}}{\partial {y}^{2}} + {F}^{Ga} - \frac{{C}^{Ga}}{{τ}^{Ga}} & [ Formula 3 ] \\ \frac{\partial {C}^{In}}{\partial t} = {D}_{S}^{In} \frac{{\partial }^{2} {C}^{In}}{\partial {y}^{2}} + {F}^{In} - \frac{{C}^{In}}{{τ}^{In}} & [ Formula 4 ]\end{matrix}$$

The superscript “Ga” to the right of a symbol in the diffusion equation means that the symbol represents a physical property value concerning the Ga atom. The superscript “In” to the right of a symbol in the diffusion equation means that the symbol represents a physical property value concerning the In atom. Ds represents the diffusion coefficient of each atom. F represents the incident flux of each atom (the flux of an atom incoming from the gas phase and impinging on the growing plane). T represents the average residence time before evaporation of each atom.

The left side of the diffusion equation of Formula 3 means the increase in density of Ga atoms per unit time at a position of the coordinate y. The left side of the diffusion equation of Formula 4 means the increase in density of In atoms per unit time at a position of the coordinate y. These are determined by subtracting, in each diffusion equation, the third term of the right side (the term which represents the rate that atoms evaporate from the growing plane) from the sum of the first term (diffusion term) and the second term (incident flux term) of the right side.

At the position of the step, atoms exhibit a specific behavior, which is different from that the atoms on the terrace exhibit. For the sake of simplicity, it is assumed that there is a step at each of the positions of y=0 and y=1. An assumption can be made that although, in crystal growth, actual steps move along the y-axis direction, the axis of y=0 (x-axis) also moves according to the movement of the steps, so that the steps always occur at the positions of y=0 and y=1. Under such an assumption, it is only necessary to solve the diffusion equation in the range of 0≦y≦1. At the positions of y=0 and y=1, i.e., at the positions of the steps, when atoms are incorporated into the crystal, the density of the atoms decreases. Also, it is necessary to consider the rate that atoms which have been once incorporated into the crystal at the positions of the steps are melted away to start moving around by diffusion over the terrace. The behavior of Ga atoms at the steps of y=0 and y=1 can be expressed by Boundary Condition 1 of Formula 5 below.

$$\begin{matrix}( Boundary Condition 1 ) & \\ Δ {N}_{sol}^{Ga} = - {ω}_{0} exp ( - \frac{{ɛ}_{sol}^{Ga} + {ɛ}_{dif}^{Ga}}{{k}_{B} T} ) Δ t + {C}_{strep}^{Ga} {ω}_{0} exp ( - \frac{{ɛ}_{dif}^{Ga}}{{k}_{B} T} ) Δ t & [ Formula 5 ]\end{matrix}$$

where the respective parameters are as follows:

ΔNₛₒₗ: net amount of each atom solidified in time Δt

ω₀: Debye frequency of each atom

k_{B}: Boltzmann constant

T: environmental temperature

εₛₒₗ: energy necessary for solidification of each atom

ε_{dif}: energy necessary for diffusion of each atom to the nearest one of adjacent sites on a crystal surface

The superscript “Ga” to the right of a symbol means that the symbol represents a physical property value concerning the Ga atom. “Cₛₜₑₚ”ᵣ which has a subscript “step”, represents the density of the atom at the position of the step. Thus, Cₛₜₑₚ=C(0) or C(1).

In Boundary Condition 1 shown above, the first term of the right side represents the amount of Ga atoms melted away from the step, and the second term represents the amount of Ga atoms solidified at the step. Thus, the formula of Boundary Condition 1 represents such a relationship of continuity that the net difference between the solidified atoms and the melted atoms is equal to the number of Ga atoms incorporated into the crystal via the step.

The above-described hypothesis can be reflected, as the simplest relationship, in the boundary condition which is employed in solving the diffusion equation of Formula 4 concerning the In atom, resulting in Boundary Condition 2 of Formula 6:

$$\begin{matrix}( Boundary Condition 2 ) & \\ Δ {N}_{sol}^{In} = - {ω}_{0} exp ( - \frac{{ɛ}_{sol}^{In} + {ɛ}_{dif}^{In}}{{k}_{B} T} ) Δ t + {C}_{step}^{In} {ω}_{0} exp ( - \frac{{ɛ}_{dif}^{In}}{{k}_{B} T} ) Δ t \times {C}_{step}^{Ga} & [ Formula 6 ]\end{matrix}$$

Here, the superscript “In” to the right of a symbol means that the symbol represents a physical property value concerning the In atom. In Boundary Condition 2, the first term of the right side represents the amount of In atoms melted away from the step, and the second term represents the amount of In atoms solidified at the step. Thus, the formula of Boundary Condition 2 represents such a relationship of continuity that the net difference between the solidified atoms and the melted atoms is equal to the number of In atoms incorporated into the crystal via the step.

Note that, as for solidification of In atoms (the second term of the right side), the influence of the density of Ga atoms at the position of the step is incorporated as a product based on the above-described hypothesis.

In solving the diffusion equation of Formula 3 concerning Ga atom and the diffusion equation of Formula 4 concerning In atom with the use of Boundary Conditions 1 and 2, it may be assumed that the atomic density distribution reaches an equilibrium sufficiently quickly as compared with the speed of advancement of the step. In that case, the left side of the diffusion equation may be approximated to 0, whereby the complexity of calculation is reduced.

The terrace between adjacent steps may be assumed as being very large on the atomic level so that the interaction between the steps can be approximately omitted. In that case, there is no problem in analyzing the essential mechanism of crystal growth.

The calculation was performed through the procedure which will be described below.

First, as for Ga atoms, the diffusion equation of Formula 3 is solved with the use of Boundary Condition 1. As a result, the density distribution of Ga atoms at the position of coordinate y on the terrace, C^{Ga}, is obtained. Therefore, the density of Ga atoms at the position of the step, C^{Ga}ₛₜₑₚ is also obtained.

Next, as for In atoms, the diffusion equation is solved with the use of Boundary Condition 2. Here, the previously-obtained Ga atom density at the position of the step, C^{Ga}ₛₜₑₚ, is used. As a result, the density distribution of In atoms at the position of coordinate y on the terrace, C^{In}, is obtained. Therefore, the gradients of the density distributions of Ga and In at the position of the step can be calculated.

The gradient of the density at the position of the step represents the variation of the density at the position of the step. This is equivalent to the net number of atoms moving toward the step, i.e., the number of Ga atoms and the number of In atoms incorporated into the crystal (the amount of solidified atoms). Here, the calculation results are shown under the assumption that melting away of Ga atoms from the step rarely occurs.

The thus-calculated amount of solidified atoms is shown along the ordinate axis of the graph of FIG. 12, and the flux of Ga atoms is shown along the abscissa axis.

### INDUSTRIAL APPLICABILITY

The present invention is probably the only method which enables formation of an InGaN layer with a high In mole fraction on the m-plane of a gallium nitride-based compound semiconductor which is free from the quantum confinement Stark effect. According to the present invention, a light-emitting device can be realized which is capable of emitting at a wavelength longer than 500 nm (green). Therefore, the wavelength range of a high efficiency light-emitting device for the next generation can be greatly increased.

### REFERENCE SIGNS LIST

101 substrate
102 n-GaN layer
103 GaN barrier layer
104 InₓGa₁₋ₓN (0<x<1) well layer
105 GaN/InGaN multi-quantum well light-emitting layer
106 p-GaN layer
107 n-electrode
108 p-electrode
201 N atom
301 substrate
302 quartz tray
303 carbon susceptor
304 quartz flow channel
305 water-cooled jacket
306 thermocouple

1. A method of manufacturing a gallium nitride-based compound semiconductor, including growing an m-plane InGaN layer whose emission peak wavelength is not less than 500 nm by metalorganic chemical vapor deposition, the method comprising the steps of:
(A) heating a substrate in a reactor; and
(B) supplying into the reactor a gas which contains an In source gas, a Ga source gas, and a N source gas, and growing an m-plane InGaN layer of an InₓGa₁₋ₓN crystal on the substrate at a growth temperature from 700° C. to 775° C.,
wherein step (B) includes setting a growth rate of the m-plane InGaN layer in a range from 4.5 nm/min to 10 nm/min.

2. A method of manufacturing a gallium nitride-based compound semiconductor, including growing an m-plane InGaN layer whose emission peak wavelength is in a range from 450 nm to 500 nm by metalorganic chemical vapor deposition, the method comprising the steps of:
(A) heating a substrate in a reactor; and
(B) supplying into the reactor a gas which contains an In source gas, a Ga source gas, and a N source gas, and growing the m-plane InGaN layer of an InₓGa₁₋ₓN crystal on the substrate at a growth temperature from 775° C. to 785° C.,
wherein step (B) includes setting a growth rate of the m-plane InGaN layer in a range from 3 nm/min to 10 nm/min.

3. A method of manufacturing a gallium nitride-based compound semiconductor, including growing an m-plane InGaN layer whose emission peak wavelength is in a range from 425 nm to 475 nm by metalorganic chemical vapor deposition, the method comprising the steps of:
(A) heating a substrate in a reactor; and
(B) supplying into the reactor a gas which contains an In source gas, a Ga source gas, and a N source gas, and growing the m-plane InGaN layer of an InₓGa₁₋ₓN crystal on the substrate at a growth temperature from 770° C. to 790° C.,
wherein step (B) includes setting a growth rate of the m-plane InGaN layer to a value which is not less than 8 nm/min.

4. A method of manufacturing a gallium nitride-based compound semiconductor, including growing an m-plane InGaN layer whose emission peak wavelength is in a range from 425 nm to 475 nm by metalorganic chemical vapor deposition, the method comprising the steps of:
(A) heating a substrate in a reactor; and
(B) supplying into the reactor a gas which contains an In source gas, a Ga source gas, and a N source gas, and growing the m-plane InGaN layer of an InₓGa₁₋ₓN crystal on the substrate at a growth temperature from 770° C. to 790° C.,
wherein step (B) includes setting a growth rate of the m-plane InGaN layer in a range from 4 nm/min to 5 nm/min.

5. A method of fabricating a semiconductor light-emitting device, comprising the steps of:
providing a substrate; and
forming a semiconductor multilayer structure on the substrate, the semiconductor multilayer structure including a light-emitting layer,
wherein the step of forming the semiconductor multilayer structure includes forming an m-plane InGaN layer according to the gallium nitride-based compound semiconductor manufacturing method as set forth in claim 24.

6. The method of claim 5, wherein
the light-emitting layer has a multi-quantum well structure, and
the m-plane InGaN layer is a well layer included in the multi-quantum well structure.

7. The method of claim 5, further comprising the step of removing the substrate.

8. A semiconductor light-emitting device, comprising:
a light-emitting layer which includes an m-plane InGaN layer that is formed according to the gallium nitride-based compound semiconductor manufacturing method as set forth in claim 24; and
an electrode for supplying electric charge to the light-emitting layer.

9. A method of claim 1, wherein, in step (b), the In source gas, the Ga source gas, and the N source gas are supplied so that Ga supply proportion is in the range from 10% to 21% and V/III ratio is not less than 1000, wherein the Ga supply proportion is ratio of the supply rate of the Ga source gas to the total supply rate of the In source gas and the Ga source gas.

10. A method of fabricating a semiconductor light-emitting device, comprising the steps of:
providing a substrate; and
forming a semiconductor multilayer structure on the substrate, the semiconductor multilayer structure including a light-emitting layer,
wherein the step of forming the semiconductor multilayer structure includes forming an m-plane InGaN layer according to the gallium nitride-based compound semiconductor manufacturing method as set forth in claim 9.

11. The method of claim 10, wherein
the light-emitting layer has a multi-quantum well structure, and
the m-plane InGaN layer is a well layer included in the multi-quantum well structure.

12. The method of claim 10, further comprising the step of removing the substrate.

13. A semiconductor light-emitting device, comprising:
a light-emitting layer which includes an m-plane InGaN layer that is formed according to the gallium nitride-based compound semiconductor manufacturing method as set forth in claim 9; and
an electrode for supplying electric charge to the light-emitting layer.

14. A method of claim 2, wherein, in step (b), the In source gas, the Ga source gas, and the N source gas are supplied so that Ga supply proportion is in the range from 7% to 21% and V/III ratio is not less than 1000, wherein the Ga supply proportion is ratio of the supply rate of the Ga source gas to the total supply rate of the In source gas and the Ga source gas.

15. A method of fabricating a semiconductor light-emitting device, comprising the steps of:
providing a substrate; and
forming a semiconductor multilayer structure on the substrate, the semiconductor multilayer structure including a light-emitting layer,
wherein the step of forming the semiconductor multilayer structure includes forming an m-plane InGaN layer according to the gallium nitride-based compound semiconductor manufacturing method as set forth in claim 14.

16. The method of claim 15, wherein
the light-emitting layer has a multi-quantum well structure, and
the m-plane InGaN layer is a well layer included in the multi-quantum well structure.

17. The method of claim 15, further comprising the step of removing the substrate.

18. A semiconductor light-emitting device, comprising:
a light-emitting layer which includes an m-plane InGaN layer that is formed according to the gallium nitride-based compound semiconductor manufacturing method as set forth in claim 14; and
an electrode for supplying electric charge to the light-emitting layer.

19. A method of claim 3, wherein, in step (b), the In source gas, the Ga source gas, and the N source gas are supplied so that Ga supply proportion is not less than 17% and V/III ratio is not less than 1000, wherein the Ga supply proportion is ratio of the supply rate of the Ga source gas to the total supply rate of the In source gas and the Ga source gas.

20. A method of fabricating a semiconductor light-emitting device, comprising the steps of:
providing a substrate; and
forming a semiconductor multilayer structure on the substrate, the semiconductor multilayer structure including a light-emitting layer,
wherein the step of forming the semiconductor multilayer structure includes forming an m-plane InGaN layer according to the gallium nitride-based compound semiconductor manufacturing method as set forth in claim 19.

21. The method of claim 20, wherein
the light-emitting layer has a multi-quantum well structure, and
the m-plane InGaN layer is a well layer included in the multi-quantum well structure.

22. The method of claim 20, further comprising the step of removing the substrate.

23. A semiconductor light-emitting device, comprising:
a light-emitting layer which includes an m-plane InGaN layer that is formed according to the gallium nitride-based compound semiconductor manufacturing method as set forth in claim 19; and
an electrode for supplying electric charge to the light-emitting layer.

24. A method of claim 4, wherein, in step (b), the In source gas, the Ga source gas, and the N source gas are supplied so that Ga supply proportion is between 9% and 11% and V/III ratio is not less than 1000, wherein the Ga supply proportion is ratio of the supply rate of the Ga source gas to the total supply rate of the In source gas and the Ga source gas.
